(19) United States
(12) Patent Application Publication
(10) Pub. No.: US 2013/0255575 A1
(43) Pub. Date: Oct. 3, 2013

(54) PLASMA GENERATOR

(71) Applicants: Jusung Engineering Co., Ltd., Gyeonggi-do (KR); Korea Advanced Institute of Science and Technology, Daejeon (KR)

(72) Inventors: Hong-Young CHANG, Daejeon (KR); Sang-Hun SEO, Daejeon (KR); Jung Hwan IN, Daejeon (KR); Hun-Su LEE, Daejeon (KR); Yun-Seong LEE, Seoul (KR)

(21) Appl. No.: 13/905,872

(22) Filed: May 30, 2013

Related U.S. Application Data
(63) Continuation of application No. PCT/KR2010/008798, filed on Dec. 9, 2010.

(51) Int. Cl. C23C 16/44

(52) U.S. Cl. CPC C23C 16/44
USPC 118/723 I

(57) ABSTRACT

Provided is a plasma generator which includes a vacuum chamber, a plurality of ground electrodes disposed inside the vacuum container and extending in parallel to each other, a plurality of power electrodes disposed between the ground electrodes inside the vacuum container, and a plurality of electrodes dielectrics disposed between the power electrodes and the ground electrodes inside the vacuum container. The power electrodes are connected to an RF power source.

### CROSS-REFERENCE TO RELATED APPLICATION

This application is a continuation of and claims priority to PCT/KR2010/008798 filed on Dec. 9, 2010, the entirety of which is hereby incorporated by reference.

### BACKGROUND OF THE INVENTION

1. Field of the Invention

The present invention relates to plasma generators and, more particularly, to a capacitively coupled plasma generator including a plurality of power electrodes and a plurality of ground electrodes.

2. Description of the Related Art

RF plasma may be classified into inductively coupled plasma and capacitively coupled plasma. Not only in a manufacturing process of solar cells but also in a manufacturing process of large-area flat panel display (FPD) devices, it is very important to uniformly generate plasma throughout a large area. A plasma process requires high plasma uniformity and high plasma density throughout a large area to achieve high process uniformity and high process speed.

Conventional capacitively coupled plasma is generated by applying an RF power source to one of facing electrodes and disposing a substrate on the other electrode. In a large area, capacitively coupled plasma exhibits low plasma uniformity and low process uniformity due to the standing wave effect.

### SUMMARY OF THE INVENTION

Embodiments of the present invention provide a plasma generator for polysilicon deposition with low lattice defect density, high growth rate, and process uniformity.

According to an embodiment of the present invention, a plasma generator may include a vacuum chamber; a plurality of ground electrodes disposed inside the vacuum container and extending in parallel to each other; a plurality of power electrodes disposed between the ground electrodes inside the vacuum container; and a plurality of electrodes dielectrics disposed between the power electrodes and the ground electrodes inside the vacuum container. The power electrodes are connected to an RF power source.

In an exemplary embodiment, the plasma generator may further include an auxiliary insulator disposed on the power electrode and the electrode dielectric. A bottom surface of the auxiliary insulator may have the same height as a top surface of the ground electrode.

In an exemplary embodiment, the vacuum container may include a top plate. The plasma generator may further include a wiring frame disposed between the top plate of the vacuum container and the auxiliary insulator.

In an exemplary embodiment, the wiring frame may include a sill therearound. The plasma generator may further include a wiring disposed inside the wring frame.

In an exemplary embodiment, the plasma generator may further include a wiring insulator disposed between the wiring and the wiring frame.

In an exemplary embodiment, the plasma generator may further include a shield part extending to the inside of the wiring frame to surround the wiring.

In an exemplary embodiment, the wiring may supply power to the power electrode at a plurality of positions.

In an exemplary embodiment, at least one of the power electrodes and the ground electrodes may include a trench disposed on its side surface or its lower surface to cause a hollow cathode discharge.

In an exemplary embodiment, each of the power electrodes or the ground electrodes may have a cylindrical shape or a polygonal pillar shape.

In an exemplary embodiment, at least one of the power electrodes and the ground electrodes may include a protrusion to extend over the electrode dielectric.

According to another embodiment of the present invention, a plasma generator may include a vacuum chamber; a plurality of ground electrodes disposed inside the vacuum container and extending in parallel to each other; a plurality of power electrodes disposed between the ground electrodes inside the vacuum container; and an electrodes dielectric disposed on the power electrode and the ground electrode inside the vacuum container. The power electrodes are connected to an RF power source.

In an exemplary embodiment, at least one of the ground electrodes and the power electrodes may have a polygonal pillar shape.

According to further another embodiment of the present invention, a plasma generator may include a vacuum container; at least one electrode structures disposed parallel to each other inside the vacuum container; substrate holders disposed to face the electrode structures; and a support structure coupled to the pair of electrode structures. The electrode structure includes a plurality of ground electrodes; a plurality of power electrodes; and a plurality of dielectrics disposed between the power electrode and the ground electrode. The power electrodes are connected to an RF power source.

In an exemplary embodiment, the substrate holders may be floated.

In an exemplary embodiment, the support structure may provide a path along which power of the RF power source is supplied to the power electrodes.

In an exemplary embodiment, at least one of the ground electrodes and the power electrodes may include a trench disposed on its top surface to cause a hollow cathode discharge.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present invention.

FIGS. 1 to 3 illustrate a plasma generator according to an embodiment of the present invention.

FIG. 4 is a top plan view of a plasma generator according to an embodiment of the present invention.

FIGS. 5 to 13 illustrate plasma generators according to other embodiments of the present invention.

FIGS. 14 to 16 illustrate a trench of a power electrode or a ground electrode according to an embodiment of the present invention.

FIG. 17 illustrates a plasma generator according to another embodiment of the present invention.

### DETAILED DESCRIPTION OF EMBODIMENTS

In a solar cell process using polysilicon, a high growth rate and a low lattice defect density of the polysilicon are required. Thus, a polysilicon plasma deposition apparatus having low lattice defect density, a high growth rate, and process uniformity is the most important in a thin film type solar cell.

The present invention will now be described more fully hereinafter with reference to the accompanying drawings, in which preferred embodiments of the present invention are shown. However, the present invention may be embodied in many different forms and should not be construed as limited to the embodiments set forth herein. Rather, these embodiments are provided so that this disclosure will be thorough and complete, and will fully convey the scope of the present invention to those skilled in the art. In the drawings, elements or components are exaggerated for clarity. Like numbers refer to like elements throughout.

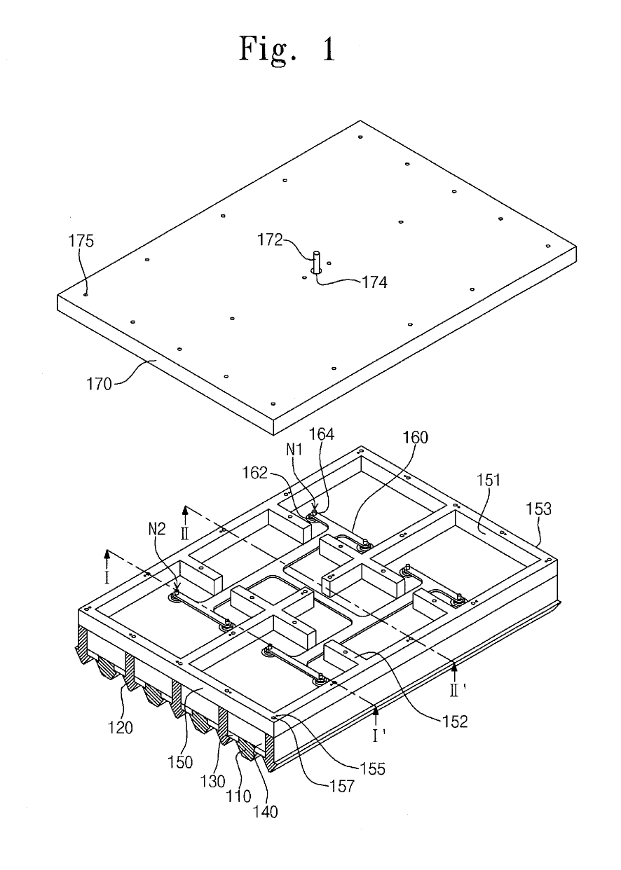

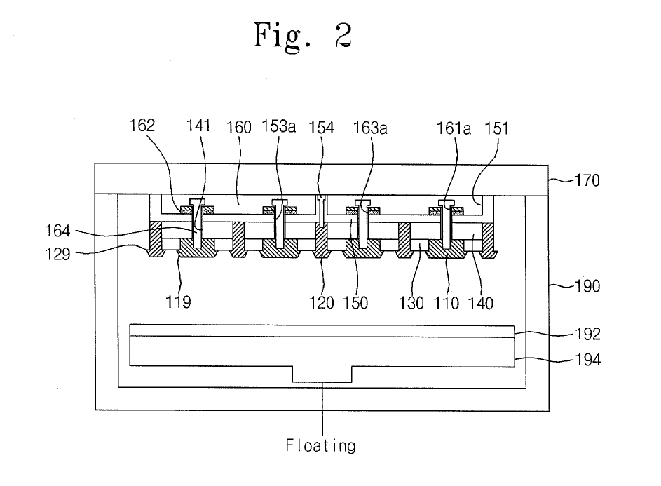

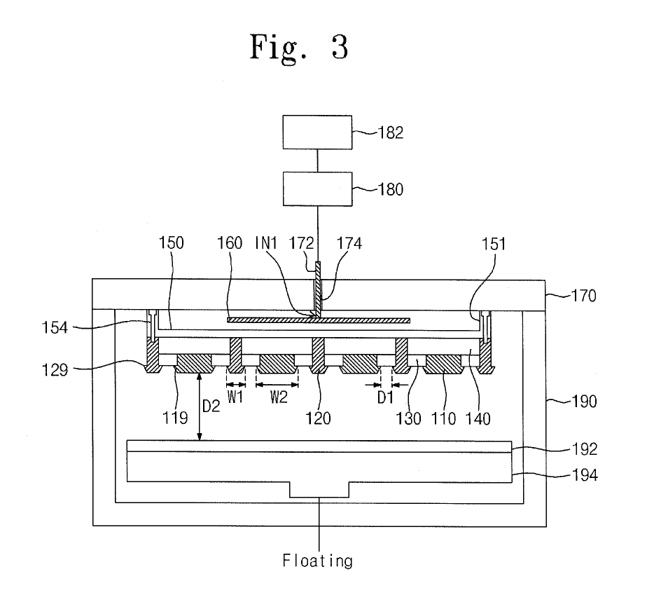

FIGS. 1 to 3 illustrate a plasma generator according to an embodiment of the present invention. FIG. 2 is a cross-sectional view taken along the line I-I′ in FIG. 1, and FIG. 3 is a cross-sectional view taken along the line II-II′ in FIG. 1.

Referring to FIGS. 1 to 3, the plasma generator includes a vacuum container 190, a plurality of ground electrodes 120 disposed inside the vacuum container and extending in parallel to each other, a plurality of power electrodes 110 disposed between the ground electrodes 190 inside the vacuum container 190, and a plurality of electrodes dielectrics disposed between the power electrodes 110 and the ground electrodes 120 inside the vacuum container 190. The power electrodes 110 are connected to an RF power source.

The vacuum container 190 may have a pressure below atmospheric pressure. The vacuum container 190 may have a rectangular parallelepiped shape. A gas inflow part (not shown) and a gas exhaust part (not shown) may be disposed at the vacuum container 190. The gas inflow part may supply a process gas to the vacuum container 190. The gas exhaust part may exhaust the process gas and reactive byproducts in the vacuum container 190 to the outside. The plasma generator may form amorphous silicon or polycrystalline silicon on a substrate 192.

The vacuum container 190 may include a top plate 170. The top plate 170 may be disposed on a top surface of the vacuum container 190. The top plate 170 may be a metal. The top plate 170 may be aluminum or stainless steel. The top plate 170 may have a square plate shape. The top plate 170 and the vacuum container 190 may be in close contact with each other to maintain vacuum.

The substrate 192 may be mounted on a substrate holder 194. The substrate holder 194 may be disposed to face the ground electrodes 120 and the power electrodes 110. The substrate 192 may be a semiconductor substrate, a glass substrate or a dielectric substrate. The substrate 192 may be a square substrate. A material deposited on the substrate 192 may be amorphous or polycrystalline silicon. The substrate holder 194 may include a heating part (not shown). The heating part may heat the substrate 192. A temperature of the substrate 192 may be a room temperature to 300 degrees centigrade. The substrate 192 or the substrate holder 194 may be electrically floated or grounded. A distance between the substrate 192 and the power electrode 110 may be less than several centimeters (cm). Since an electric potential of the substrate 192 moves with a plasma potential when the substrate 1921 is floated, the energy of ions impinging on the substrate 192 is low. Thus, damage of a thin film caused by the ions may be reduced.

In case of typical capacitively coupled plasma, voltages applied to sheaths of a ground electrode a power electrode spaced to face each other are nearly equivalent to each other. Consequently, in this case, a thin film formed on a substrate disposed on the ground electrode is damaged by high-energy ions.

Each of the ground electrodes 120 may have a square pillar shape. The ground electrodes 120 may be disposed between the power electrodes 110 and both sides of the power electrodes 110. The ground electrodes 120 may be electrically grounded. The power electrode 110 and the ground electrode 120 may form a cathode and an anode, respectively. A distance D1 between the power electrode 110 and the ground electrode 120 may be smaller than a distance D2 between the power electrode 110 and the substrate 192. Accordingly, a strong electric field may be established between the power electrode 140 and the ground electrode 122 to generate plasma. In addition, plasma supplied to the substrate 192 may impinge on the substrate 192 with low ion energy. Thus, the plasma generator may provide low lattice defect during a silicon deposition process. When the substrate 192 is floated, the plasma is mainly established between the ground electrode 120 and the power electrode 110. The ground electrode 120 may include a protrusion 129. The protrusion 129 may be means for coupling with an electrode dielectric 130.

Each of the power electrodes 110 may have a square pillar shape. A section of the power electrode 110 may have a different shape than that of the ground electrode 120. The power electrode 110 may include a protrusion 119. The protrusion 119 may be means for coupling with the electrode dielectric 130.

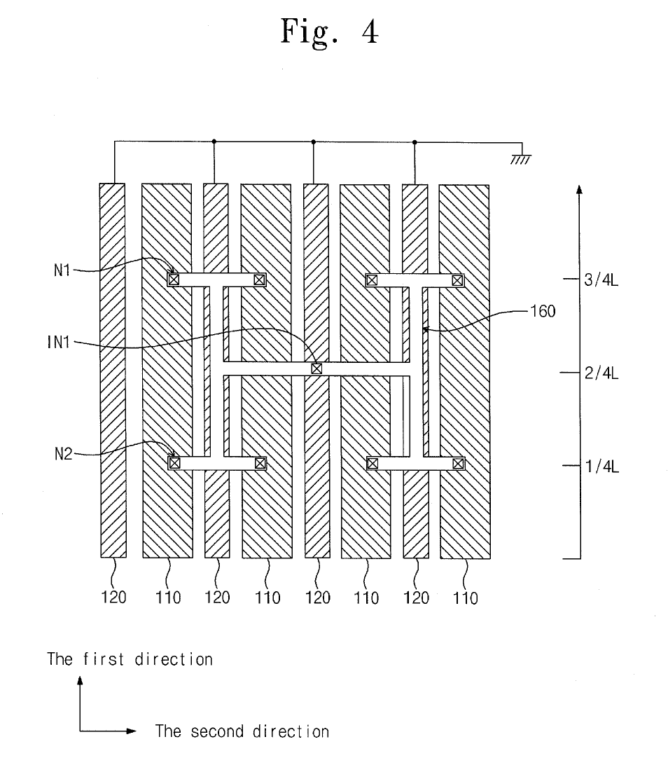

FIG. 4 is a top plan view of a plasma generator according to an embodiment of the present invention.

Referring to FIGS. 1 to 3 and FIG. 4, if a frequency of an RF power source 182 increases, plasma density may increase. However, if the frequency of the RF power source 182 increases, the standing wave effect may increase. The standing wave effect may restrict plasma uniformity and/or process uniformity. Supply of RF power to a plurality of nodes N1 and N2 of the power electrode 110 may reduce the standing wave effect. A plasma density distribution may vary depending on positions where RF power is supplied to the power electrode 110.

Each of the power electrodes 110 may be equally divided into N parts. The RF power is supplied to a center portion of the divided N part of the power electrode 110. That is, the nodes N1 and N2 of the power electrode 110 may be disposed on the center portion of the divided part. A current distribution and/or a voltage distribution of the power electrode 110 may be symmetrical with respect to the center of the power electrode 110.

Each of the power electrodes 110 may include a plurality of nodes N1 and N2. The nodes N1 and N2 may supply power of the RF power source 182 to the power electrode 110. The nodes N1 and N2 may include a first node N1 and a second node N2. A length of the power electrode 110 is L. The first node N1 may be disposed at L/4, and the second node N2 may be disposed at 3L/4. At the nodes N1 and N2, current may have the maximum while a voltage may have the minimum. A distribution of the current or the voltage may be horizontally symmetric with respect to the center of the nodes N1 and N2. Phases of voltages at the nodes N1 and N2 may be in-phase.

Returning to FIGS. 1 to 3, the electrode dielectrics 130 may electrically isolate the power electrode 110 and the ground electrode 120 from each other. Each of the electrode dielectrics 130 may be alumina, quartz, ceramic or silicon. The electrode dielectrics 130 may be supported by the protrusion 129 of the ground electrode 120 and the protrusion 119 of the power electrode 110. Each of the electrode dielectrics 130 may be alumina or ceramic that has superior resistance against sputtering.

A top surface of the electrode dielectric 130 may match that of the power electrode 110. An auxiliary dielectric 140 may be disposed on the power electrode 110 and the electrode dielectric 130. A top surface of the auxiliary dielectric 140 may match that of the ground electrode 120. The auxiliary dielectric 140 may be Teflon, ceramic, silicon or alumina The auxiliary dielectric 140 may have a plurality of through-holes 141. The power of the RF power source 182 may be supplied to the power electrode 110 by a power source connection part 164 disposed to penetrate the through-hole 141.

A wiring frame 150 may be disposed on the ground electrode 110 and the auxiliary dielectric 140. The wiring frame 150 may include a sill 151 disposed therearound. The wiring frame 150 may be electrically connected to the ground electrode 120 while being in contact with the ground electrode 120. In addition, the wiring frame 150 may be fixedly connected to the ground electrode 120 through fixing means 154 disposed to penetrate the through-hole 157. The wiring frame 150 may have a nut hole 155. The nut hole 155 may be fixedly connected to a bolt (not shown) disposed to penetrate a through-hole 175 formed in the top plate 170.

A wiring 160 may be disposed inside the wiring frame 150 to supply power to the power electrodes 110. The wiring 160 may supply power to a single power electrode 110 at a plurality of positions. A wiring insulator 162 may be disposed between the wiring 160 and the wiring frame 150 to electrically insulate the wiring and the wiring frame 150 from each other. The wiring 160 may have a wiring through-hole 161a, the wiring insulator 162 may have an insulating through-hole 163a, and the wiring frame 150 may have a frame through-hole 153a. The auxiliary dielectric 140 may have an auxiliary through-hole 141. The wiring through-hole 161a, the insulating through-hole 163a, the frame through-hole 153a, and the auxiliary through-hole 141 may be aligned with each other. The power source connection part 164 may be electrically connected to the power electrode 110 through the wiring through-hole 161a, the insulating through-hole 163a, the frame through-hole 153a, and the auxiliary through-hole 141. In addition, the power source connection part 164 may fixedly connect the wiring 160 and the power electrode 110 to each other.

A frequency of the RF power source 182 may be 1 MHz or higher. Preferably, the frequency of the RF power source 182 may be 1 MHz to 200 MHz. An impedance matching circuit 180 may be disposed between the RF power source 182 and a wiring input terminal IN1. The impedance matching circuit 180 may be means for maximally transferring the power of the RF power source 182 to a load. The RF power source 182 may supply power to the wiring input terminal IN1 through a power supply line 174. The power supply line 174 and the top plate 170 may be sealed.

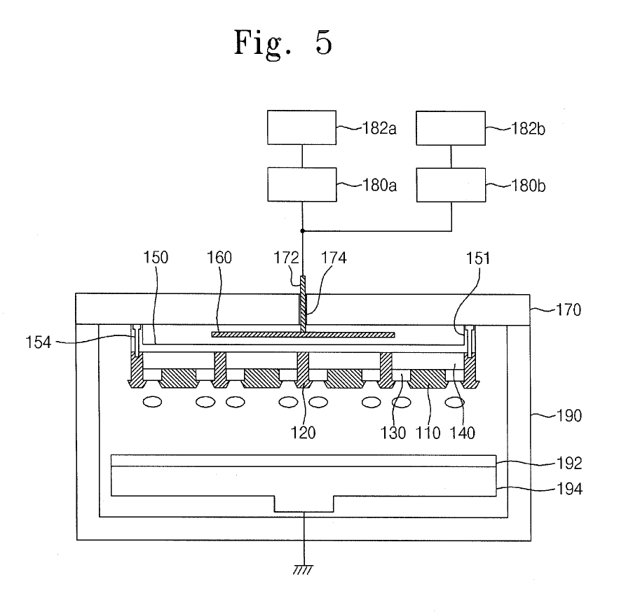

FIGS. 5 to 13 illustrate plasma generators according to other embodiments of the present invention. In FIGS. 5 to 13, the same elements as those in FIGS. 1 and 3 will be designated by the same reference numerals and will not be described in further detail. Moreover, in FIGS. 5 to 13, sections different from FIGS. 1 and 3 will be extensively described to avoid duplicate description.

Referring to FIG. 5, an RF power source may include a first RF power source 182a and a second RF power source 182b. A frequency of the first RF power source 182a may be greater than that of the second RF power source 182b. The first RF power source 182a and the second RF power source 182b may be connected in parallel. The frequency of the first RF power source 182a may be 10 MHz to 100 MHz. The frequency of the second RF power source 182b may be 1 MHz to 10 MHz. The first RF power source 182a may supply power to a power electrode 110 through a first impedance matching circuit 180a. The second RF power source 182b may supply power to the power electrode 110 through a second impedance matching circuit 180b. A substrate holder 192 may be grounded or floated.

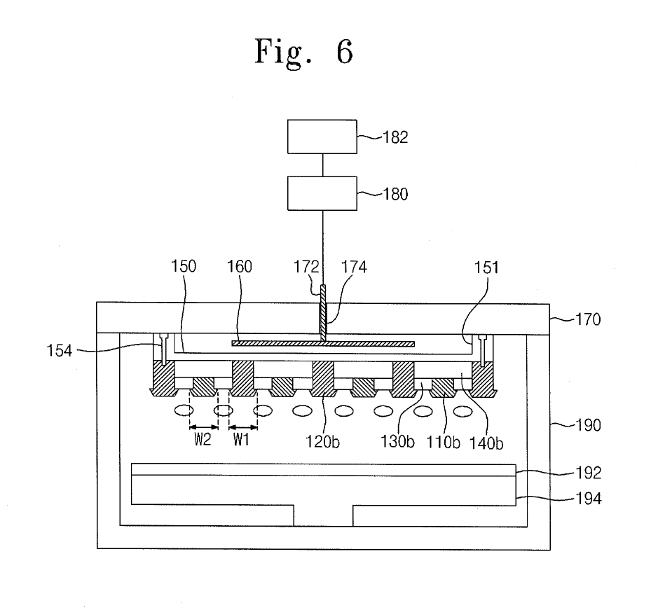

Referring to FIG. 6, width W1 of a ground electrode 120b may be equal to width W2 of a power electrode 110b. According to a modified embodiment of the present invention, the width W1 of the ground electrode 120b, the width W2 of the power electrode 110b, and a ground dielectric 130b may be variously changed.

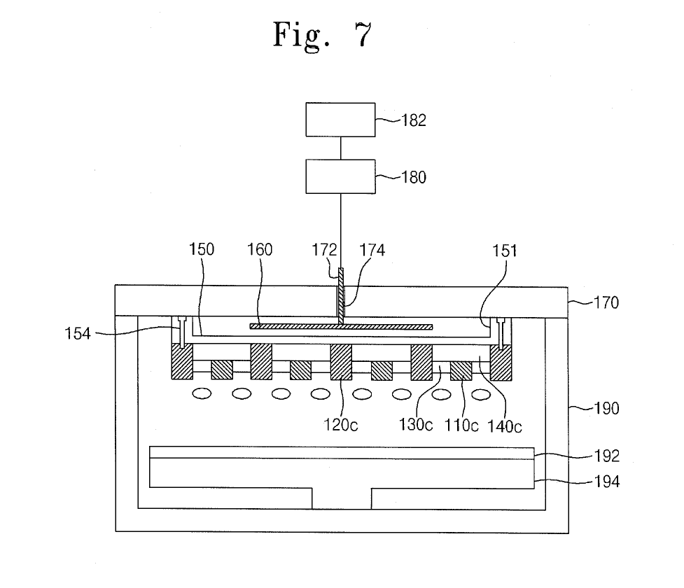

Referring to FIG. 7, a section of a ground electrode 120c may have a square shape. A section of a power electrode 110c may have a square shape. The ground electrode 120c, the power electrode 110c, and an electrode dielectric 130c may have various shapes.

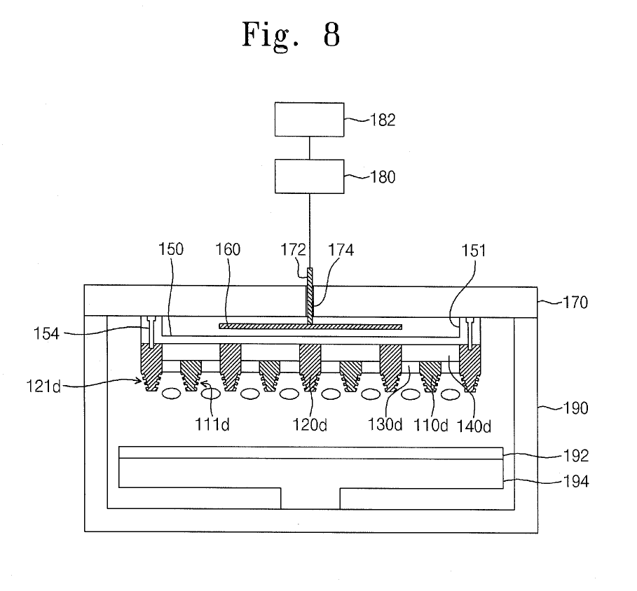

Referring to FIG. 8, a section of a ground electrode 120d may be hexagonal. A section of a power electrode 110d may be hexagonal. Three surfaces of the ground electrode 120d and the power electrode 110d may be exposed on an electrode dielectric 130d. A power trench 111d may be disposed in a portion of or the entire portion of the exposed power electrode 110d. A ground trench 121d may be disposed in a portion of or the entire portion of the exposed ground electrode. The power trench 111d and a ground trench 121d may each have a hole shape. Sections of the power trench 111d and the ground trench 121d may each have a shape of circle, ellipse, polygon or trench. The trenches 121d and 111d may cause a hollow cathode discharge. The trenches 121d and 111d may have a constant density or shape in an extending direction of the power electrode 110d or the ground electrode 120d. According to a modified embodiment of the present invention, the trench 121d and 111d may have different densities or shapes in the extending portion of the power electrode 110d or the ground electrode 120d to ensure process uniformity.

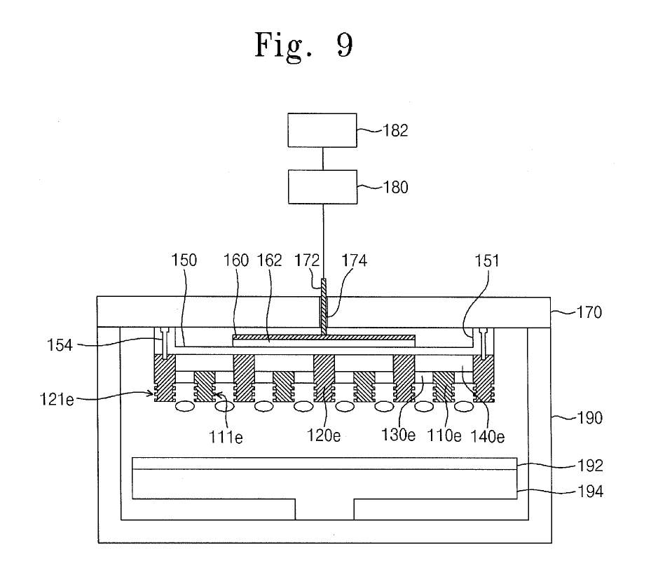

Referring to FIG. 9, a section of a ground electrode 120e may be rectangular. A section of a power electrode 110e may be rectangular. Portions of the ground electrode 120e and the power electrode 110e may be exposed. A distance between the ground electrode 120e and the power electrode 110e may be constant.

A power trench 111e may be disposed on a side surface of the exposed power electrode 110e. The ground trench 121e may be disposed on a side surfaced of the exposed ground electrode 120e. Each of the trenches 111e and 121e may have a hole shape. Sections of each trench 111e and 121e may each have a shape of circle, ellipse or polygon.

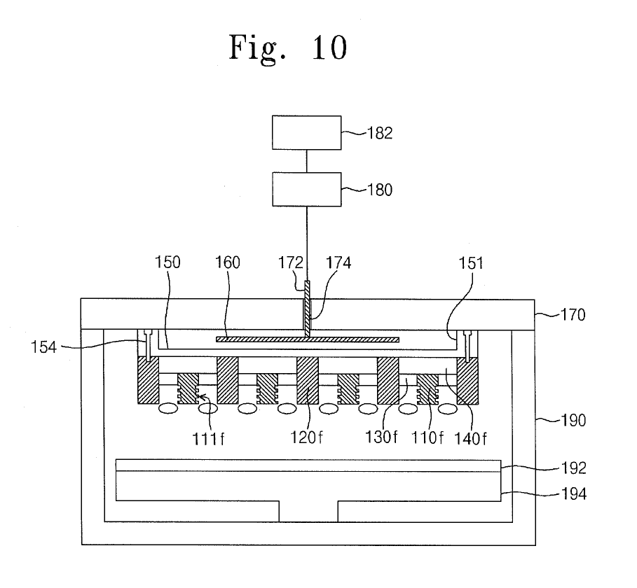

Referring to FIG. 10, a section of a ground electrode 120f may be rectangular. A section of a power electrode 110f may be rectangular. Portions of the ground electrode 120f and the power electrode 110f may be exposed. A distance between the ground electrode 120f and the power electrode 110f may be constant. A power trench 111f may be disposed on a side surface of the exposed power electrode 110f. The trench 111f may have a hole shape. Sections of the trench 111f may have a shape of circle, ellipse or polygon.

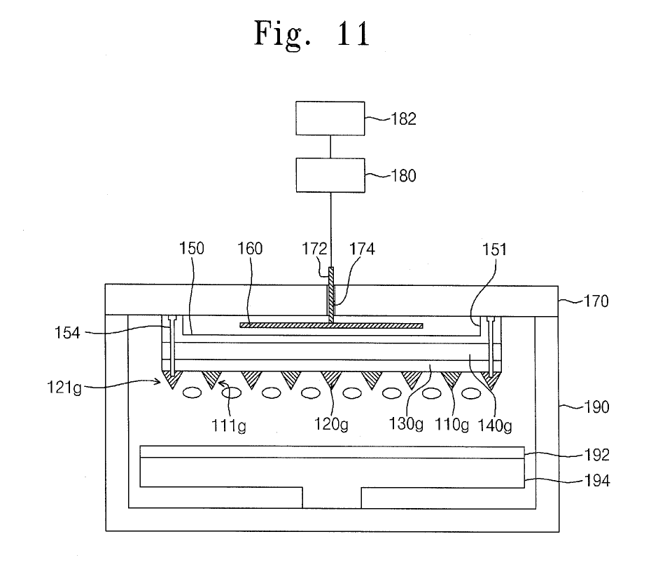

Referring to FIG. 11, a section of a ground electrode 120g may be trigonal. A section of a power electrode 110g may be trigonal. An electrode dielectric 130g may be disposed on the ground electrode 120g and the power electrode 110g. Optionally, an auxiliary dielectric 140g may be disposed on the electrode dielectric 130g. Two surfaces of the ground electrode 120g and the power electrode 110g may be disposed on the electrode dielectric 130g. The electrode dielectric 130g may be disposed on a plurality of power electrodes 110g and a plurality of ground electrodes 120g. According o a modified embodiment of the present invention, the ground electrode 120g and the power electrode 110g may have various shapes such as polygon, circle, ellipse and the like.

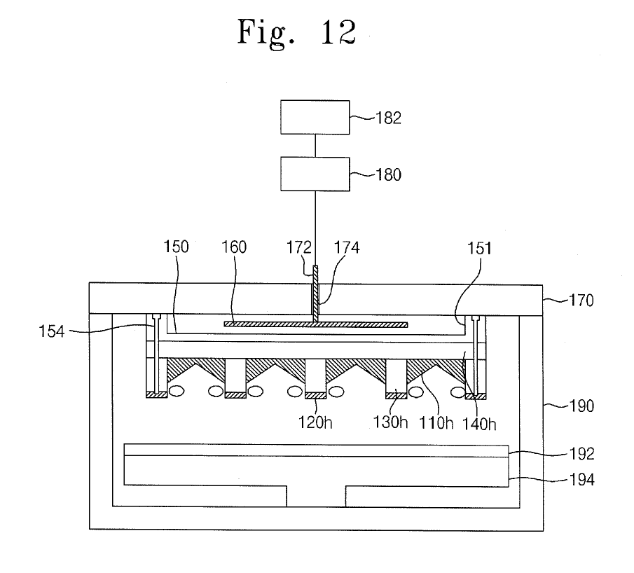

Referring to FIG. 12, a section of a ground electrode 120h may be rectangular. A section of a power electrode 110h may be pentagonal. An electrode dielectric 130h may be disposed on both sides of the power electrode 110h. The ground electrode 120h may be disposed on a lower surface of the electrode dielectric 130h. A lower surface of the power electrode 110h may be higher than that of the electrode dielectric 130h. Pentagon may be provided by recession in the center of an exposed portion of the power electrode 120h.

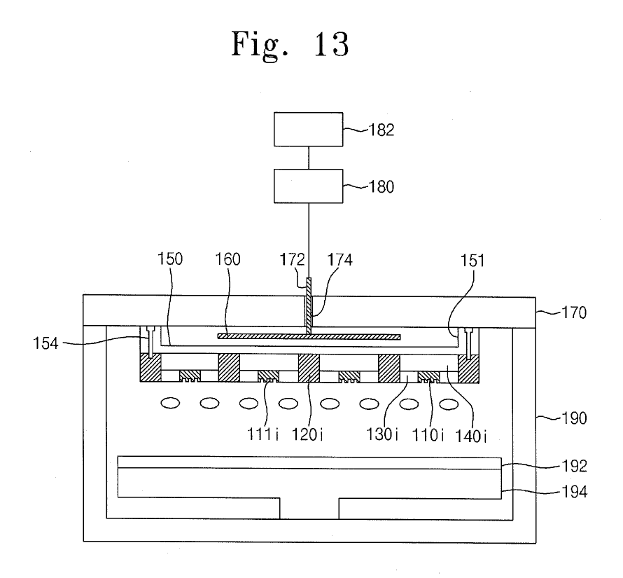

Referring to FIG. 13, a section of a ground electrode 120i may be rectangular. A section of a power electrode 110i may be rectangular. An electrode dielectric 130i may be disposed between the power electrode 110i and the ground electrode 120i. Lower surfaces of the electrode dielectric 130i, the power electrode 120i, and the ground electrode 110i may match each other. An exposed surface of the power electrode 110i may include a trench 111i.

FIGS. 14 to 16 illustrate a trench of a power electrode or a ground electrode according to an embodiment of the present invention.

Referring to FIG. 14, a power electrode 210 may have a truncated prism shape. The power electrode 210 may include trenches 211. A section of the trench 211 may be circular or elliptical. Depth, radius, and density of the trench portion 211 may be selected to ensure maximum plasma density or process uniformity under a process condition.

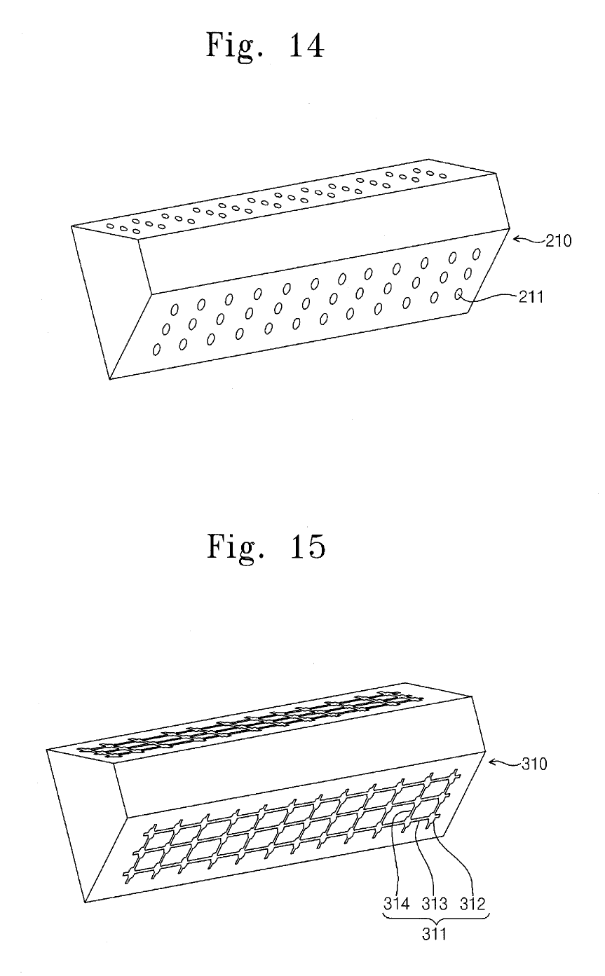

Referring to FIG. 15, a power electrode 310 may have a truncated prism shape. The power electrode 310 may include a plurality of trenches 311. The trench 311 may include two-dimensionally and regularly arranged holes 312, and vertical trenches 313 connecting the holes 312 and horizontal trenches 314 intersecting the vertical trenches 313 in the form of cross on a plane where the holes 312 are arranged.

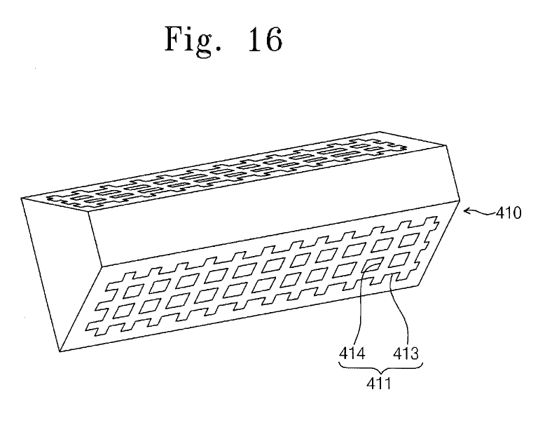

Referring to FIG. 16, a power electrode 410 may have a truncated prism shape. The power electrode 410 may include a plurality of trenches 411. The trenches 411 may include vertical trenches 413 and horizontal trenches 414 intersecting the vertical trenches 413 connected in the form of cross,

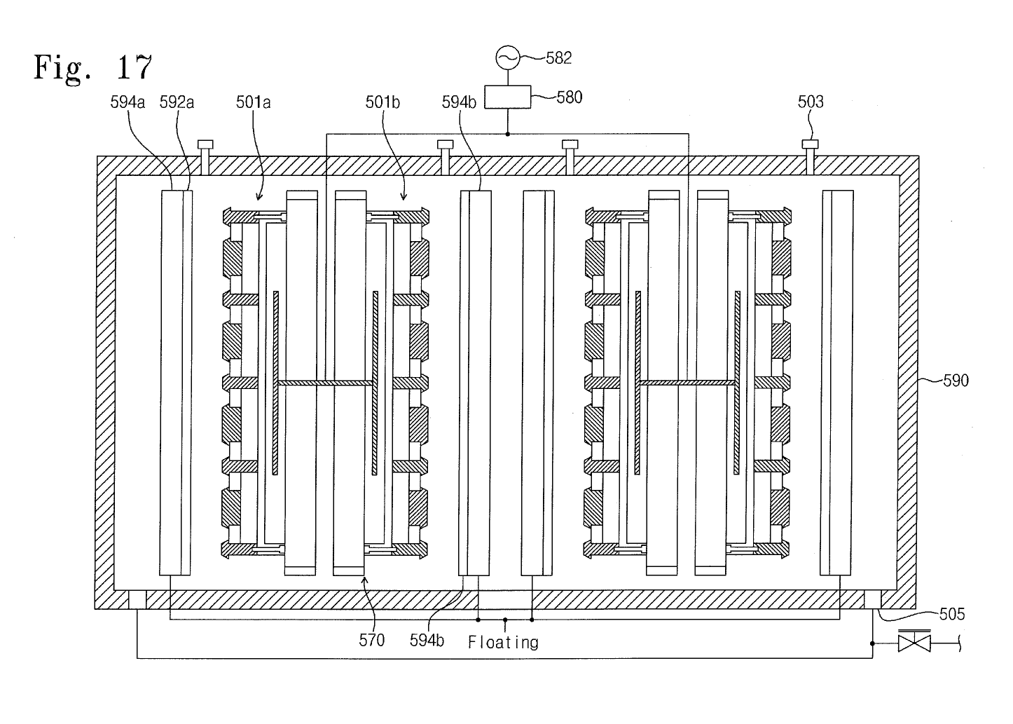

FIG. 17 illustrates a plasma generator according to another embodiment of the present invention.

Referring to FIG. 17, the plasma generator may include a vacuum container 590, at least one pair of electrode structures 501a and 501b disposed parallel to each other inside the vacuum container 590, substrate holders 594a and 594b disposed to face the electrode structures 501a and 501b, and a support structure 570 coupled to the pair of electrode structures 501a and 501b. The electrode structures 501a and 501b includes a plurality of ground electrodes, power electrodes disposed between the ground electrodes, and dielectric disposed between the power electrode and the ground electrode. The power electrodes are connected to an RF power source 582. The electrode structures 501a and 501b may be identical to those explained in FIGS. 5 to 13.

The vacuum container 590 may have a pressure below atmospheric pressure. The vacuum container 590 may have a rectangular parallelepiped shape. A plurality of gas inflow parts 503 and a plurality of gas exhaust parts 505 may be disposed at the vacuum container 590. The gas inflow part 503 may supply a process gas to the vacuum container 590. The gas exhaust part 505 may exhaust the process gas and reactive byproducts in the vacuum container 590 to the outside. The plasma generator may form amorphous silicon or polycrystalline silicon on a substrate 592a.

The substrate holders 594a may be floated. The substrate 592a may be mounted on the substrate holder 594a and disposed to face the electrode structure 501a.

The support structure 570 may provide a path along which power of the RF power source 582 is supplied to the power electrodes. The inside of the support structure 570 may be filled with an insulator or be in atmospheric pressure. At least one of the ground electrodes and the power electrodes may include a trench having a surface on which hollow cathode discharge is caused.

According to a modified embodiment of the present invention, a plasma generator may be applied even in the case where a circular substrate is mounted. Thus, a power electrode and/or a ground electrode may be arranged in an azimuthal direction.

As described so far, a plasma generator according to an embodiment of the present invention may have a structure of divided power electrodes. Divided ground electrodes may be disposed adjacent to the divided power electrodes. The power electrodes and the ground electrodes may generate plasma. The power electrodes and the ground electrodes may be disposed on the substantially same plane to provide low-energy plasma to a substrate that is perpendicularly spaced apart from the power electrodes. Thus, a thin film having low lattice defects may be formed on the substrate. The thin film may be polycrystalline silicon or amorphous silicon. In addition, the power electrode or the ground electrode may include a trench. The trench may provide a hollow cathode discharge to improve plasma density. Thus, process speed may be improved.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A plasma generator comprising:
a vacuum chamber;
a plurality of ground electrodes disposed inside the vacuum container and extending in parallel to each other;
a plurality of power electrodes disposed between the ground electrodes inside the vacuum container; and
a plurality of electrode dielectrics disposed between the power electrodes and the ground electrodes inside the vacuum container,
wherein the power electrodes are connected to an RF power source.

2. The plasma generator as set forth in claim 1, further comprising an auxiliary insulator disposed on the power electrode and the electrode dielectric,
wherein a bottom surface of the auxiliary insulator has the same height as a top surface of the ground electrode.

3. The plasma generator as set forth in claim 2, wherein the vacuum container includes a top plate, and
the plasma generator further comprising a wiring frame disposed between the top plate of the vacuum container and the auxiliary insulator.

4. The plasma generator as set forth in claim 3, wherein the wiring frame includes a sill therearound, and
the plasma generator further comprising a wiring disposed inside the wring frame.

5. The plasma generator as set forth in claim 4, further comprising a wiring insulator disposed between the wiring and the wiring frame.

6. The plasma generator as set forth in claim 4, further comprising a shield part extending to the inside of the wiring frame to surround the wiring.

7. The plasma generator as set forth in claim 4, wherein the wiring supplies power to the power electrode at a plurality of positions.

8. The plasma generator as set forth in claim 1, wherein at least one of the power electrodes and the ground electrodes includes a trench disposed on its side surface or its lower surface to cause a hollow cathode discharge.

9. The plasma generator as set forth in claim 1, wherein each of the power electrodes or the ground electrodes has a cylindrical shape or a polygonal pillar shape.

10. The plasma generator as set forth in claim 1, wherein at least one of the power electrodes and the ground electrodes includes a protrusion to extend over the electrode dielectric.

11. A plasma generator comprising:
a vacuum chamber;
a plurality of ground electrodes disposed inside the vacuum container and extending in parallel to each other;
a plurality of power electrodes disposed between the ground electrodes inside the vacuum container; and
an electrodes dielectric disposed on the power electrode and the ground electrode inside the vacuum container,
wherein the power electrodes are connected to an RF power source.

12. The plasma generator as set forth in claim 11, wherein at least one of the ground electrodes and the power electrodes has a polygonal pillar shape.

13. A plasma generator comprising:
a vacuum container;
at least one electrode structures disposed parallel to each other inside the vacuum container;
substrate holders disposed to face the electrode structures; and
a support structure coupled to the pair of electrode structures,
wherein the electrode structure comprises:
a plurality of ground electrodes;
a plurality of power electrodes; and
a plurality of dielectrics disposed between the power electrode and the ground electrode, and
wherein the power electrodes are connected to an RF power source.

14. The plasma generator as set forth in claim 13, wherein the substrate holders are floated.

15. The plasma generator as set forth in claim 13, wherein the support structure provides a path along which power of the RF power source is supplied to the power electrodes.

16. The plasma generator as set forth in claim 13, wherein at least one of the ground electrodes and the power electrodes includes a trench disposed on its top surface to cause a hollow cathode discharge.
